(19) United States
(12) Patent Application Publication
(10) Pub. No.: US 2024/0404742 A1
(43) Pub. Date: Dec. 5, 2024

(54) Single and Multiple Pole Magnetics Module Integral to Power Converter Module

(71) Applicant: Harold EICHER, New York, NY (US)

(72) Inventor: Harold EICHER, New York, NY (US)

(73) Assignee: Harold EICHER, New York, NY (US)

(21) Appl. No.: 18/670,303

(22) Filed: May 21, 2024

Related U.S. Application Data
(60) Provisional application No. 63/505,103, filed on May 31, 2023.

(51) Int. Cl. H01F 27/24; H01F 27/28; H05K 1/18

(52) U.S. Cl. CPC H01F 27/24; H01F 27/2804; H05K 1/181; H05K 2201/08

(57) ABSTRACT

The present invention discloses several means for combining together electrically and physically a single or multi-pole discrete magnetic device structure into an external main power-processing assembly or structure, which contains power semiconductor components and other power components. The point of interface and electrical connection mainly consists of winding terminations, power semiconductors and capacitors and creating the most optimum path for high frequency current flow and distribution in that region. This invention discloses several optimum methods for combining the two structures not previously done in prior art. In addition, the disclosure resolves how to optimize the high frequency current distribution at the point of connection or interface of the two discrete assemblies. It does so by creating interleaving layers of countervailing current flow and parallel paths of current flow on each layer at the interface or connection point of the two discrete assemblies.

### CROSS-REFERENCE TO RELATED APPLICATIONS

Provisional Application No. 63/505,103 filed May 31, 2023.

### PRIOR ART

The discussion of such novel structures begins with a discussion of the prior art. Referring to FIG. 1, typical approaches have as their separate structures a substrate 107 which contains the power and other components required and another structure, the magnetic element or composite component, consisting of elements 101 through 106. The magnetic composite structure may contain one or more substrates such as 101 and 102 which are typically multi-layer windings implemented on one or more layers. These windings are typically conductive traces interspersed with insulation layers and may or may not contain one or more components mounted within or on the top or bottom surfaces in some hybrid fashion. In this illustration the prior art is comprised of two magnetic pole elements 103. The multi-pole magnetic elements are typically of a ferromagnetic material due to the high frequencies employed. Obscured by this view are the actual pole structures which connect magnetic elements 103 and 104. These magnetic elements contain the flux generated by the flow of currents in windings within the substrates 101 and 102 in accordance with the particular power topology considered. The magnetic pole structures themselves can assume varied and different shapes and locations within the intervening space between 103 and 104. Some means of connecting the winding elements or layers of conductive traces to external circuitry contained within a separate component assembly on substrate 107 is necessary. This is accomplished with input connection terminals 105 and output terminals 106 as shown in FIG. 1.

The magnetic structure connects to substrate 107 electrically at positions 109 for terminals 105 and positions 110 for terminals 106. It connects mechanically to the substrate 107 thought apertures or windows in the substrate at location 108. In most instances in commercial use there is no aperture and the magnetic structure mounts on the top [or bottom] of the substrate 107. The power components and other components are mounted on the substrate in locations 111 and 112. The prior art embodiment shown in FIG. 1 is intended for clarity of discussion, showing the two separate structures and discussing one method of connecting the two together. There are innumerate variations of this prior art employed in various ways but they all fall within this basic constraint as shown and described.

### BACKGROUND OF THE INVENTION

The field of electronic power conversion main objectives typically are highest efficiency in the smallest volume yielding the highest output power. The problem faced is how to couple together two disparate structures, namely the magnetic elements and the other components. Of the many examples of innovative techniques and methods employed that couple the magnetic elements to all the associated power and other components, the typical approach is to integrate the magnetic elements and components into one composite structure, i.e. an embedded structure or module. Another approach optimizes a discrete magnetic structure independently and then incorporates that into a separate discrete structure or assembly that contains the other components required. The critical point of incorporation occurs at the junction of the winding terminations, the power semiconductor components, and the filter capacitors. It is more difficult to make that connection with two discrete assemblies as opposed to an embedded one which contains the two, by design and function. That difficulty requires compromises to be made and it is in the detail of those compromises that emerge various novel techniques for addressing the issue. The advent of higher frequencies and use of multi-pole magnetic structures creates novel pressures and opportunities for considering the best method to combine the two. This invention and disclosure relates to several optimum methods for combining the two structures not previously contemplated.

### SUMMARY OF THE INVENTION

The present invention and disclosure provides several means and methods for combining together electrically and physically a single or multi-pole discrete magnetic device assembly or structure into an external main power-processing assembly or structure, which contains the power semiconductor components and other components necessary for the processing of electrical power. The point of interface and electrical connection mainly consists of winding terminations, power semiconductors and capacitors and creating the most optimum path for high frequency current flow and distribution in that region. The present invention and disclosure demonstrates methods to make that difficult connection with the two discrete assemblies as opposed to an embedded one. This invention and disclosure relates to several optimum methods for combining the two structures not previously contemplated.

One problem to be solved in connecting these two, or more, structures together electrically is to optimize the high frequency current distribution thereby optimizing the efficiency and power processing at the point of connection or interface of the two discrete assemblies. This invention and disclosure solves this problem by creating interleaving layers of countervailing current flow and parallel paths of current flow on each layer at the interface or connection point of the two discrete assemblies.

Another problem to be solved in combining two separate and discrete composite structures, is that any solution is particular or unique to that one solution and optimized accordingly. There is no universal solution, only particular ones. This invention and disclosure solves the problem by creating a universal and expandable means of optimizing both separate structures to most closely proximate that of one singular composite structure.

Another problem to be solved is that the magnetic pole piece or core elements that make up the magnetic structure must be fabricated in a mold and that imposes size and shape limitations as a consequence which limits the amount power processing capability and dictates the size the complete assembly must be.

This invention and disclosure solves the problem by creating separate magnetic element piece parts that can be constructed to form a whole magnetic structure and such individual elements are not constrained by current mold-making or manufacturing techniques.

Furthermore, the corresponding apertures in the magnetic substrate can adapt readily to meet whatever size the apertures assume.

Another problem to be solved is to find a method in which the discrete magnetic substrate layers and the discrete power component substrate layers can most closely proximate the combined embedded magnetic and power component substrate layers. This invention and disclosure solves the problem by creating a separate hybrid substrate comprised of one or a number of layers that share space within the magnetic layer stack structure of the core window with the substrates or conductive winding layers therein. Said separate substrate in one exemplary embodiment contains the power components. Said separate substrate may also contain windings themselves utilized as part of the magnetic element.

Another problem to be solved for high frequency power conversion is to minimize proximity effect and loop inductance within multiple layers of the substrate of the magnetic assembly. This invention and disclosure solves the problem by configuring the magnetic assembly substrate layers wherein current flowing in all layers across from insulated interfaces occurs in instances where there are opposing directions of current flow in adjacent layers or regions. Furthermore, the configuration links together conductive current regions or traces on one layer with conductive regions or traces on other layers either adjacent or disposed a further distance away in the layer stack. It repeats this for other layers within the substrate and creates the maximum number of regions and layers within a given layer stack that can share current in this manner. This “layer jump” methodology improves performance by creating lowest ac proximity loss and overall copper loss, lowest MMF lines of flux between layers, and lowest and balanced leakage inductance between windings in a coupled magnetic device and also distributes same balance amongst all of the poles used in the ferromagnetic structure. In addition, one exemplary embodiment, it does so in a manner that creates isolated regions located sufficient distance from the magnetic structures preserving the dielectric creepage distance required of power conversion equipment.

Another problem to be solved is that to connect discrete magnetic substrates to power semiconductor components at the periphery is in general difficult to implement optimally to maximize high frequency current distribution. It is easier in embedded structures where the component can be placed directly above the windings of the magnetic substrate which is also part of the embedded structure. However, for a discrete device, the windings must terminate somewhere and then the connections for the power semiconductor components can occur. This is an inevitable tradeoff in utilizing discrete or separate structures. This invention and disclosure solves the problem by creating separate carrier substrates for power components mounted vertically at the interface of the magnetic winding substrate terminations or interface connection. Said carrier substrates contain within interleaving layers and parallel paths for current flow at that interface or connection point. The configuration of the carrier substrate layers links together conductive current regions or traces on one layer with conductive regions or traces on other layers either adjacent or disposed a further distance away in the layer stack. The power semiconductors mounted thereon experience improved current distribution resulting in lowest ac proximity loss, overall copper loss, lowest MMF lines of flux between layers and component, and lowest, balanced loop inductance to the power semiconductor component.

The aforementioned difficulty to connect discrete magnetic substrates to power semiconductor components at the periphery to maximize high frequency current distribution can be solved in another way. This invention and disclosure solves the problem by co-locating the terminal positions for both the magnetic composite substrate and the external power component substrate which thereby occupy the same position or location on both substrates. A concentric cylinder pin terminal structure makes this possible. The cylindrical structure of the terminal and its concentricity with the central pin creates a means of countervailing or opposing current flow both within the terminal and at the terminal interface which maximizes efficiency, particularly at high frequencies.

There is another all encompassing approach utilizing the above techniques to connect discrete magnetic substrates to power semiconductor components at the periphery. This invention and disclosure solves the problem by creating a greater number of magnetic flux poles which thereby create a greater number of quadrants in which to mount the power semiconductor components in either horizontal or vertical fashion. This affords more flexibility in the design and overall construction as portions of the construction can be changed or adapted without affecting other parts of the construction. However, expanding the number of poles is most effective when the multiple pole pieces are configures as separable pole pieces. This takes advantage of the scalability and universality such approach affords.

Another problem to be solved is the separate discrete assembly consisting of substrate and mounted power components also has mounted thereon many other components dedicated to control, management and auxiliary functions. For an embedded module, this is an issue as well. However, this takes up space and is difficult to package when the power conversion module consists of two discrete assemblies this invention or disclosure is dealing with. This invention and disclosure solves the problem by creating a substrate area or region comprised of only those components necessary to core power conversion function and places associated components related to management, function, and control offloaded to the external assembly or structure to which the power conversion module connects. The interface and signals from this separate assembly connect to the composite dedicated power conversion module with a suitable connector. This simplifies the overall concept.

### BRIEF DESCRIPTION OF DRAWINGS

The invention and description throughout refers to a discrete and separate magnetic substrate which, with other magnetic elements and components, forms a composite structure that is referred to as an Integrated Magnetic Module. In addition, the invention and description throughout refers to a separate discrete power-processing substrate which, along with other components, forms a composite structure that is referred to as an Integrated Power Conversion Module.

FIG. 1 is an isometric and exploded view of Prior Art.

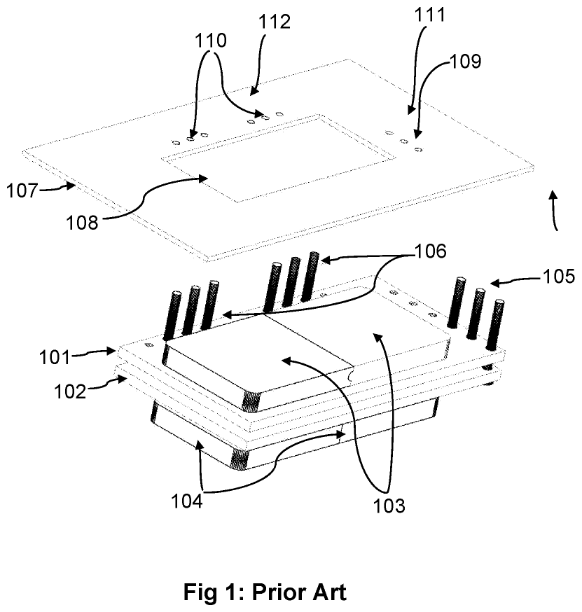

FIG. 2 is an isometric and exploded view of a first exemplary embodiment of the invention.

FIG. 3 is an isometric and exploded view of the Integrated Magnetic Module as the first exemplary embodiment of the invention.

FIG. 4 is an isometric and exploded view of one embodiment of the layer structure of the Integrated Magnetic Module substrate.

FIG. 5 is an isometric and exploded view of another aspect of the first exemplary embodiment of the invention with multiple poles.

FIG. 6 is an isometric and exploded view of one aspect of the Integrated Magnetic Module with a separate bottom plate.

FIG. 7 is an isometric and exploded view of another aspect of the first exemplary embodiment of the invention disclosing only incorporated power components.

FIG. 8 is an isometric and exploded view of another exemplary embodiment of the invention wherein the Integrated Power Conversion Module is inserted into the layer stack along with the Integrated Magnetic Module.

FIG. 9 is an isometric and exploded view of another exemplary embodiment of the invention wherein the Integrated Power Conversion Module has carrier substrates located at the periphery that contain power semiconductor components.

FIG. 10 is an isometric and exploded view of one possible aspect of the detail of the carrier substrates mounted on the Integrated Power Conversion Module.

FIG. 11 is an isometric and exploded view of another exemplary embodiment of the invention with multiple quadrants.

FIG. 12 is an isometric and exploded view of another exemplary embodiment of the invention wherein the Integrated Magnetic Module and the Integrated Power Conversion Module share the same proximate position for the terminals that connect the two at the interface or connection point. heading is required.

### DETAILED DESCRIPTION OF THE INVENTION

The present invention and disclosure provides several means and methods for combining together electrically and physically a single or multi-pole discrete magnetic device assembly or structure into an external main power-processing assembly or structure, which contains the power semiconductor components and other components necessary for the processing and conversion of electrical power. The present invention discloses several embodiments to make that interconnection at the interface for the most optimum path for high frequency current flow and distribution in that region with the two discrete assemblies or structures. The invention and description throughout refers to a discrete and separate magnetic substrate which, with other magnetic elements and components, forms a composite structure that is referred to as an Integrated Magnetic Module. In addition, the invention and description throughout refers to a separate discrete power-processing substrate which, along with other components, forms a composite structure that is referred to as an Integrated Power Conversion Module.

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

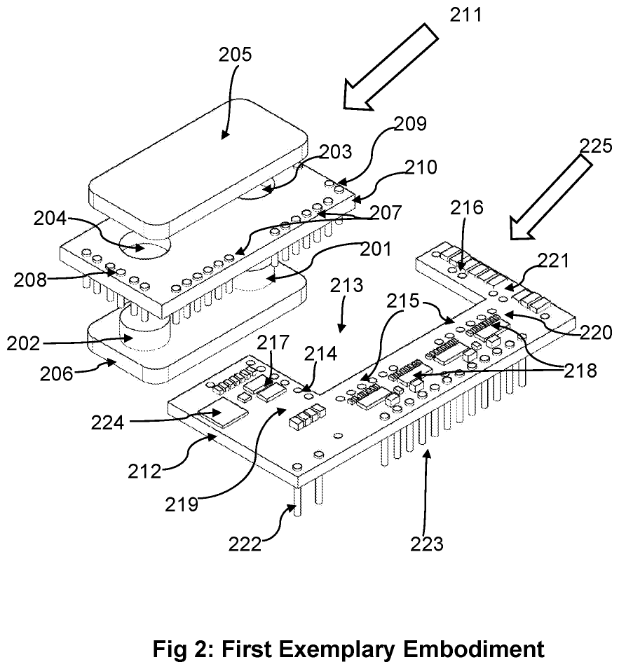

Referring to FIG. 2, a first exemplary embodiment may include a magnetic pole piece or shape 201 and at least one additional magnetic pole piece or shape 202, typically ferromagnetic; at least one substrate layer 210 which contains the windings, e.g. pcb traces; an aperture 203 in substrate layer 210 into which one magnetic pole piece 201 is inserted and at least one additional aperture 204 in substrate layer 210 into which magnetic pole piece 202 is inserted. The first exemplary embodiment may also include a magnetic baseplate 206 which secures in position magnetic pole pieces 201 and 202 and a magnetic top plate 205 which, along with baseplate 206, may typically be ferromagnetic, forms a cover and return path for the magnetic flux of the composite magnetic structure. In this first exemplary embodiment, the composite structure is 2-pole but the disclosure and concept readily encompass and apply to multiple poles. The substrate 210 contains at least one output terminal 207, at least one input terminal 208, and typically, at least one intermediate terminal 209. The component parts 201 through 210 form a composite structure 211 which is a discrete magnetic device described as an Integrated Magnetic Module which is one claim of the invention, and within its component parts and construction therein are contained other novel aspects that have separable claims as part of this disclosure.

Continuing with the description with regard to FIG. 2, the present invention may include at least one additional external substrate 212; at least one cut-out 213 in said substrate into which at least one or more of the magnetic composite structure components 201, 202, 205, and 206 are to be inserted; at least one terminal position 214, in this first exemplary embodiment, a plated thru hole into which will be inserted at least one of the Integrated Magnetic Module input terminals 208; at least one terminal position 215 into which will be inserted at least one of the Integrated Magnetic Module output terminals 207; and may include at least one terminal position 216 into which will be inserted at least one of the Integrated Magnetic Module intermediate terminals 209; at least one substrate Input-Side area or region for installed power semiconductor components 217; at least one substrate Output-Side area or region for installed power semiconductor components 218; at least one substrate Input-Side area or region comprised of top, bottom and inner layers of the substrate interleaved for high frequency, high current flow and return on adjacent layers in opposing directions 219; at least one substrate Output-Side area or region comprised of top, bottom and inner layers of the substrate interleaved for high frequency, high current flow and return on adjacent layers in opposing directions 220; and may include at least one intermediate area or region comprised of top, bottom and inner layers of the substrate interleaved for high frequency, high current flow and return on adjacent layers in opposing directions 221; at least one input terminal 222; at least one output terminal 223; and may include at least one area or region comprised of associated components necessary for general power conversion management, function, and control 224. The component parts 212 through 224 form a discrete composite structure or Integrated Power Converter Module 225.

The Integrated Magnetic Module or structure 211 inserted into the Integrated Power Converter Module or structure 225, together form a completed Power Conversion Module, which, in this exemplary embodiment is designed for high frequency, high power DC-DC conversion.

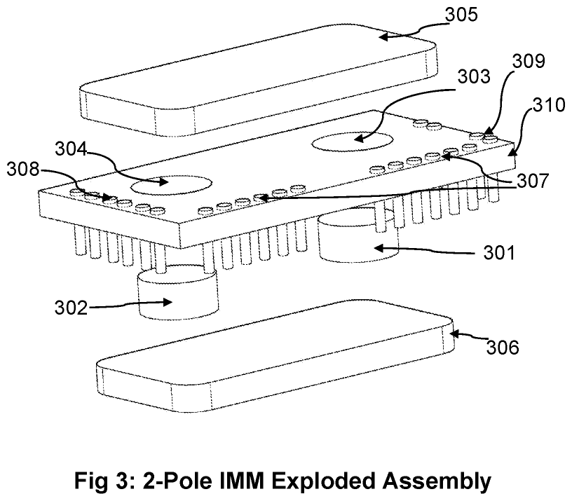

FIG. 3 discloses another aspect and further detail and embodiment of the Integrated Magnetic Module. As in the FIG. 2 first exemplary embodiment, FIG. 3 includes a separate magnetic pole piece 301, an additional separate magnetic pole piece 302, at least one substrate 310 which contains the windings, and along with the magnetic structure components, forms the discrete device described as an Integrated Magnetic Module in the first exemplary embodiment. FIG. 3 also includes an aperture 303 in substrate 310 into which magnetic pole piece 301 is inserted, an aperture 304 in substrate 310 into which magnetic pole piece 302 is inserted, a magnetic baseplate 306 which secures in position magnetic pole pieces 301 and 302, a magnetic top plate 305 which forms a cover and return path for the magnetic flux of the composite magnetic structure, at least one substrate output terminal 307; at least one substrate input terminal 308 and may include at least one substrate intermediate terminal 309. The component parts 301 and 302 are shown in FIG. 3 as separable elements. That is, they are not physically the same homogenous structure as the baseplate 306. They need not be fabricated in the same step as the baseplate either through mold or CNC machining. They are fabricated separately as separate items. As separate items, they form specific disclosures as part of this invention. There are limits in magnetic device mold making that constrain the size of a homogeneous component formed together utilizing 301, 302 and 306. The size limitation becomes more pronounced as the number of magnetic pole pieces, 301 and 302, increases from two to four, or more. The only recourse for larger sizes is to machine the ferromagnetic component out of a block. This is much more costly compared to a mold. There is no such limit in size when fabricating 301, 302 or 306 as separate magnetic elements. The significance is that a magnetic structure composed of elements 301, 302, 305, and 306 can assume any size of any variation and is not subject to limiting factors in fabrication. Pole pieces 301 and 302 can be secured to the baseplate 306 in a further manufacturing step. They can be located in position on baseplate 306 by features in the baseplate and/or features in the substrate 310. These location features demonstrate further aspects of the disclosure.

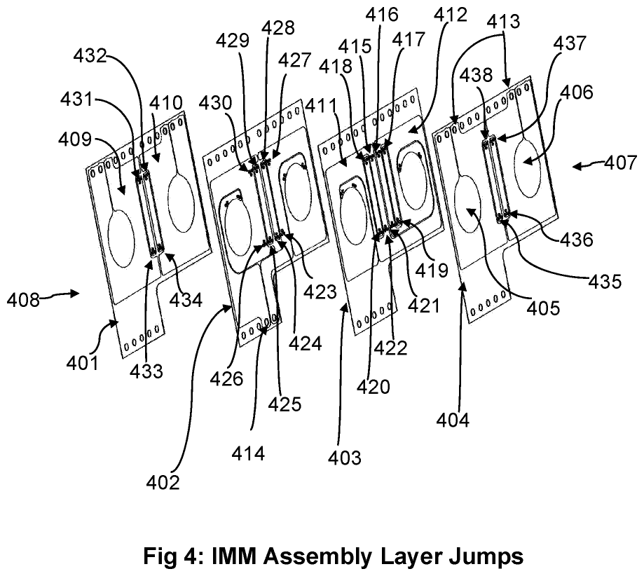

In another embodiment of the disclosure, FIG. 4 shows embedded layers of the substrate which forms one of the component parts of the Integrated Magnetic Module in the FIG. 2 first exemplary embodiment. This aspect of the disclosure configures the magnetic assembly substrate layers wherein current flowing in all layers across from insulated interfaces occurs in instances where there are opposing directions of current flow in adjacent layers or regions. This configuration links together conductive current regions or traces on one layer with conductive regions or traces on other layers either adjacent or disposed a further distance away in the layer stack. It repeats this for other layers within the substrate and creates the maximum number of regions and layers within a given layer stack that can share current in this manner.

There are apertures in each layer through which the pole pieces of the magnetic pole pieces are designed to pass through. These apertures correspond to pole-1 405 and pole-2 406. In one possible embodiment, these apertures have centering structures or fingers which help to locate and center the individual ferromagnetic cylinders so they can be secured to one of the magnetic base plates, top or bottom.

In one possible embodiment, four layers are shown in FIG. 4. Moving from left to right, which corresponds to a layer order from the bottom 408 towards the top of the window 407 of the magnetic core structure, we have the first layer at the bottom, layer 401, which is one of the secondary layers with a copper trace 409 shown for pole number one and a copper trace 410 shown for pole number two. Moving towards the right or up in the layer stack, we have layer 402. This is one of the primary layers and a copper trace is shown both for pole number one and pole number two. The copper trace for pole-1 has two interlayer vias 426 and 430 which are part of or make direct connection to that copper trace. On layer 404 these connect to or jump to layer 404 vias at 435 and 438 and the isolated island copper trace between these two vias on layer 404 is one way that the pole-1 primary layer 402 can have a direct connection on an adjacent secondary layer two layers further removed in the layer stack. Similarly, the copper trace for pole-2 on layer 402 has two interlayer vias 423 and 427 which are part of or make direct connection to this copper trace. On layer 404 these connect to vias at 436 and 437 and the isolated island copper trace between these two vias on layer 404 is one way that the pole-2 primary layer 402 can have a direct connection to an adjacent secondary layer two layers further removed in the layer stack.

In addition, layer 402 primary pole-1 vias 426 and 430 make connection or jump to layer 403 primary to vias at 418 and 420 and the isolated island copper trace between these two vias on layer 403 is one way that the pole-1 primary layer 402 can have a direct connection on an adjacent primary layer. Layer 402 pole-2 primary interlayer vias 423 and 427 make connection or jump to layer 403 primary vias at 417 and 419 and the isolated island copper trace between these two vias on layer 403 is one way that the pole-2 primary layer 402 can have a direct connection on an adjacent primary layer.

Moving towards the right or up in the layer stack, we have layer 403. This is one of the primary layers and a copper trace is shown both for pole number one and pole number two. The copper trace for pole-1 has two interlayer vias 415 and 422 which are part of or make direct connection to this copper trace. On layer 403 these connect to or jump to layer 401 vias at 431 and 433 and the isolated island copper trace between these two vias on layer 401 is one way that the pole-1 primary layer 403 can have a direct connection on an adjacent secondary layer two layers further removed in the layer stack. Similarly, the copper trace for pole-2 on layer 403 has two interlayer vias 416 and 421 which are part of or make direct connection to this copper trace. On layer 401 these connect to vias at 432 and 434 and the isolated island copper trace between these two vias on layer 401 is one way that the pole-2 primary layer 403 can have a direct connection to an adjacent secondary layer two layers further removed in the layer stack.

In addition, layer 403 primary pole-1 vias 415 and 422 make connection or jump to layer 402 primary to vias at 425 and 429 and the isolated island copper trace between these two vias on layer 402 is one way that the pole-1 primary layer 403 can have a direct connection on an adjacent primary layer. Layer 403 pole-2 primary interlayer vias 416 and 421 make connection or jump to layer 402 primary vias at 424 and 428 and the isolated island copper trace between these two vias on layer 402 is one way that the pole-2 primary layer 403 can have a direct connection on an adjacent primary layer. The secondary layers 401 and 404 have provisions for connection to external circuitry such as the Integrated Power Conversion Module with terminals that are inserted in positions 413. The primary layers 402 and 403 have provisions for connection to external circuitry such as Integrated Power Conversion Module with terminals that are inserted in positions 414.

A specific claim for this invention and shown in the embodiment is that the isolated regions are located sufficient distance from the magnetic pole pieces preserving the dielectric creepage distance required of much electronic power conversion equipment. It is also at such location that the minimum area required at that layer to form the isolated trace or region does not subtract significantly from the overall copper area and thus preserves a nominal current density. It is also at such location that the current flow occurs in a region of highest magnetic flux concentration. It is also a claim of this invention to utilize two or more of these regions as needed per each pole. The layer order in this embodiment is but one possibility but the method applies to whichever layer order one wishes to implement to achieve further interleaving of layers.

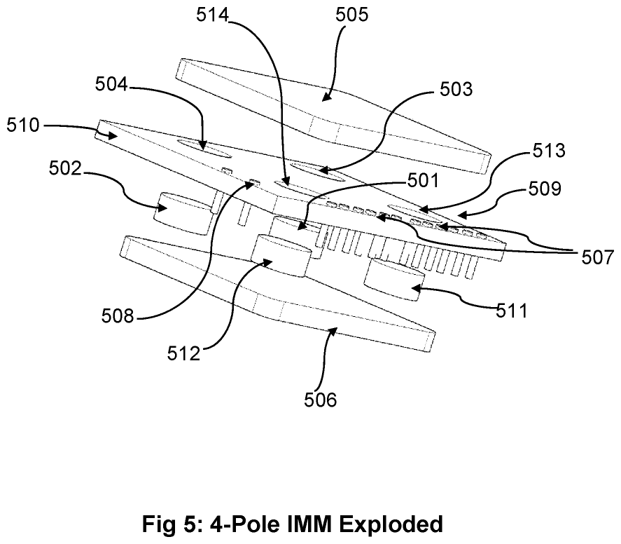

FIG. 5 discloses another exemplary embodiment to connect discrete magnetic substrates to power semiconductor components, in this aspect, at the periphery of the separate power-processing substrate. This disclosure creates a greater number of magnetic poles which thereby create a greater number of quadrants in which to mount the power semiconductor components in either horizontal or vertical fashion. FIG. 5 includes separate magnetic pole pieces 501 and 502 as in previous embodiments. It adds two more separate magnetic pole pieces 511 and 512 in order to derive a 4-pole magnetic core structure. As in FIGS. 2 and 3, there is at least one substrate layer 510 which contains the windings, and along with the magnetic core structure, forms the discrete device described as an Integrated Magnetic Module in the first exemplary embodiment, except, in this case, it forms a quad-pole version.

FIG. 5 drawing includes an aperture 503 in substrate layer 510 into which magnetic pole piece 501 is inserted and an aperture 504 in substrate layer 510 into which magnetic pole piece 502 is inserted. Since it is a quad-pole, FIG. 5 drawing further includes an aperture 513 in substrate layer 510 into which magnetic pole piece 511 is inserted and an aperture 514 in substrate layer 510 into which magnetic pole piece 512 is inserted. As in previous embodiments, FIG. 5 includes a magnetic baseplate 506 which secures in position magnetic pole pieces 501, 502, 511 and 512; magnetic top plate 505 which forms a cover and return path for the magnetic flux of the composite magnetic structure; at least one discrete magnetic structure substrate output terminal 507; at least one input terminal 508 and may include at least one intermediate terminal 509. The component parts 501, 502, 511 and 512 are shown in FIG. 5 as separable elements. That is, they are not physically the same homogenous structure as baseplate 506. They are not fabricated in the same step as the baseplate either through mold or CNC machining. They are fabricated separately as separate items. There are limits in magnetic device mold making that constrain the size of a homogeneous component formed together utilizing 501, 502, 511, 512 and 506. The size limitation becomes more pronounced as the number of magnetic pole elements, e.g., 511, 512, increases from two to four. There is no such limit in size when fabricating 501, 502, 511, 512 and 506 as separate magnetic elements. Elements 501, 502, 511 and 512 can be secured to the baseplate 506 in a further manufacturing step. They can be located in position on the baseplate 506 by features in the baseplate and/or features in the substrate 510, said features which constitute claims of the invention.

The overall approach of this construction affords more flexibility in the design and manufacture as portions of the construction can be changed or adapted without affecting other parts of the construction. However, expanding the number of poles is most effective when the multiple pole pieces are configured as separable pole pieces. This takes advantage of the scalability and universality such approach affords.

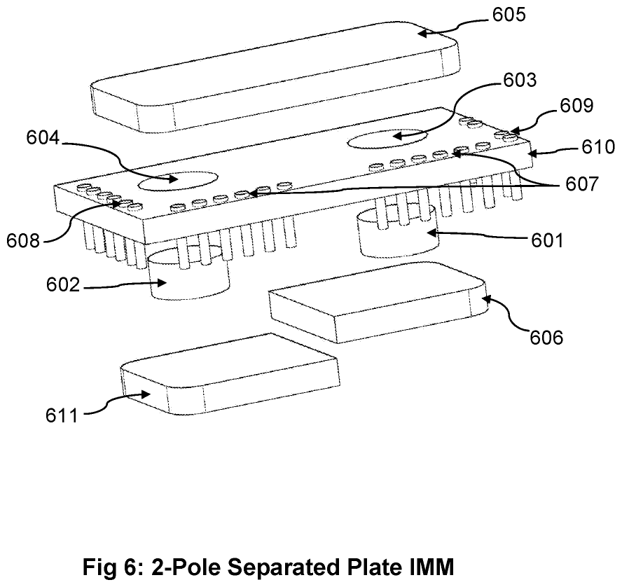

FIG. 6 discloses another aspect of the embodiment of FIG. 3 Integrated Magnetic Module. FIG. 6 includes a separate magnetic pole piece 601, an additional separate magnetic pole piece 602, and at least one substrate layer 610 which contains the windings. FIG. 6 also includes an aperture 603 in substrate layer 610 into which the magnetic pole piece 601 is inserted, an aperture 604 in substrate layer 610 into which magnetic pole piece 602 is inserted, one separable magnetic baseplate 606 which secures in position magnetic pole piece 601, and another separable magnetic baseplate 611 which secures in position magnetic pole piece 602. FIG. 6 also includes a magnetic top plate 605 which forms a cover and return path for the magnetic flux of the composite magnetic structure, at least one substrate output terminal 607, at least one substrate input terminal 608, and may include at least one substrate intermediate terminal 609.

In this embodiment, in addition to the magnetic pole pieces 601 and 602 being separable elements, the baseplate is as well separated into two pieces 606 and 611. As with FIG. 3 embodiment, there are limits in magnetic device mold making that constrain the size of a homogeneous component formed together utilizing 601, 602, 606 and 611. There is no such limit in size when fabricating 601, 602, 606 or 611 as separate magnetic elements. The significance is that a magnetic structure composed of elements 601, 602, 605, 606 and 611 can assume any size of any variation and is not subject to limiting factors in fabrication. The separable baseplates 606 and 611 form a further embodiment that adds flexibility to the size, location and design of the pole pieces 601, 602 and substrate 610.

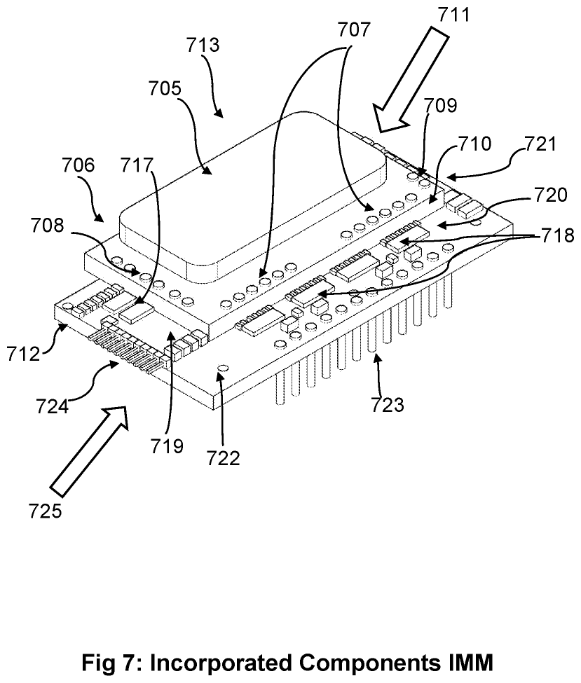

FIG. 7 discloses another embodiment of the separate power-processing substrate structure by creating an area or region comprised of only those components necessary to core power conversion function and places associated components related to management, auxiliary function, and control offloaded to the external assembly or structure to which the power conversion module connects. The interface and signals from this separate substrate assembly connect to the external assembly with a suitable connector.

Referring to FIG. 7 this aspect of an embodiment includes at least two separate magnetic pole pieces. They are not shown in this embodiment as the Integrated Magnetic Module is shown inserted into the motherboard and they are obscured in this view. The same applies to the apertures in substrate 710 into which the pole pieces are inserted. There is at least one substrate layer 710 which contains the windings. There is a magnetic base plate [obscured] and a top plate 705 which forms a cover and return path for the magnetic flux of the composite magnetic structure. There is at least one substrate output terminal 707, at least one substrate input terminal 708, and may have at least one substrate intermediate terminal 709.

The FIG. 7 disclosure includes at least one Integrated Power Converter Module substrate layer 712 and at least one cut-out 713 [obscured] in said substrate into which the Integrated Magnetic Module is shown inserted. The terminal positions in substrate 712 are obscured as they are occupied by the Integrated Magnetic Module terminals, which in this embodiment are shown inserted in position. There is at least one Integrated Power Conversion substrate top and bottom layer Input-Side for installed power semiconductor components 717 and at least one substrate top and bottom layer Output-Side for installed power semiconductor components 718. The Integrated Power Conversion Module substrate has an Input-Side area or region comprised of top, bottom and inner layers of the substrate interleaved for high frequency, high current flow and return on adjacent layers in opposing directions 719, at least one substrate Output-Side area or region comprised of top, bottom and inner layers of the substrate interleaved for high frequency, high current flow and return on adjacent layers in opposing directions 720, and may have at least one substrate intermediate area or region comprised of top, bottom and inner layers of the substrate interleaved for high frequency, high current flow and return on adjacent layers in opposing directions 721. There is at least one substrate input terminal 722 and at least one substrate output terminal 723.

This FIG. 7 embodiment differs from the first exemplary embodiment in that the Integrated Power Conversion Module substrate area or region does not incorporate associated components necessary for general power conversion management, auxiliary function, and control. In this embodiment, such functions are offloaded to an external separate assembly. The interface and signals from this separate assembly connect to the Integrated Power Conversion Module with a suitable connector shown in this embodiment as 724.

Another exemplary embodiment of the invention discloses a method in which the Integrated Power Conversion power-processing substrate is inserted into the layer stack of the Integrated Magnetic Module device substrate. In this embodiment, the Integrated Power Conversion power-processing substrate continues to function as the motherboard substrate which contains power components necessary for the processing and conversion of electrical power. The Integrated Magnetic Module substrate continues its function of having constituent layers form its substrate and containing the windings of the composite magnetic structure. It apportions one or more layers therein for the power-processing substrate to contain incorporated power components and thus approximates an embedded structure. It creates a separate hybrid substrate comprised of one or a number of layers that share space within the magnetic layer stack structure of the magnetic core window with the substrates or conductive winding layers therein. Said separate substrate in this exemplary embodiment contains the power components. Said separate substrate may also contain windings themselves utilized as part of the magnetic structure.

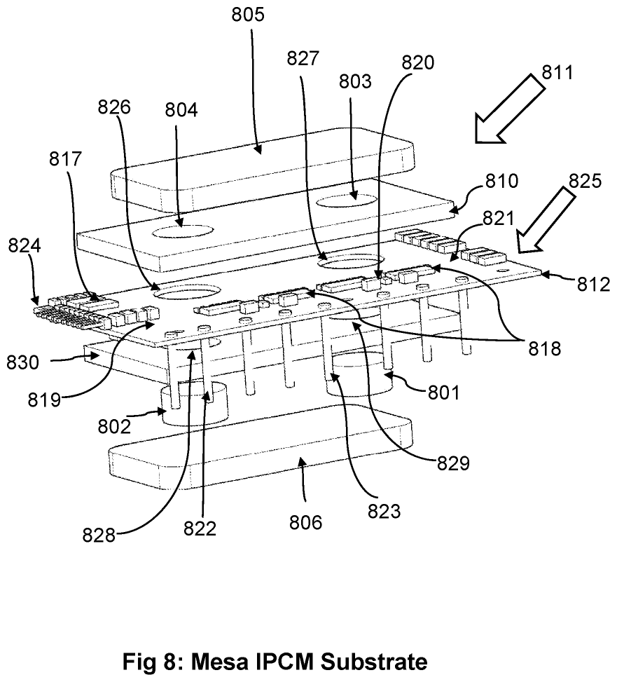

Referring to FIG. 8 the disclosure shows a separate magnetic pole piece 801, an additional separate magnetic pole piece 802, at least one substrate layer 810 and preferably, an additional substrate layer 830, both of which contain the windings, and at least one or more additional substrate layers 812 which contain incorporated power components mounted on it. Inserted into the layer stack along with 810 and 830 in combination, and, along with the magnetic structure, it forms a composite device or structure described as a combined Integrated Magnetic Module and Integrated Power Conversion Module. Furthermore, the present disclosure contains an aperture 803 in Integrated Magnetic Module substrate layer 810 into which magnetic pole piece 801 is inserted; an aperture 827 in Integrated Power Conversion Module substrate layer 812 into which magnetic pole piece 801 is inserted and an aperture 829 in Integrated Magnetic Module substrate layer 830 into which magnetic pole piece 801 is inserted. Furthermore, the present disclosure contains an aperture 804 in Integrated Magnetic Module substrate layer 810 into which magnetic pole piece 802 is inserted, an aperture 826 in Integrated Power Conversion Module substrate layer 812 into which magnetic pole piece 802 is inserted and an aperture 828 in Integrated Magnetic Module substrate layer 830 into which magnetic pole piece 802 is inserted. This embodiment further utilizes a magnetic baseplate 806 which secures in position magnetic pole pieces 801 and 802, and a magnetic top plate 805 which provides a cover and return path for the magnetic flux of the composite magnetic structure so formed.

Other embodiments of this disclosure would include at least one Integrated Magnetic Module substrate output terminal, at least one substrate input terminal and may include at least one substrate intermediate terminal. These terminals in substrate 810 would connect to the Integrated Power Conversion Module substrate 812. Substrate 812 would have corresponding terminal positions for accepting the connections from the 810 terminal positions. That is one method this embodiment can also implement. Other methods include connection via pads, castellations, or terminals specially designed for this connection. It also includes embedding substrate 812 along with substrates 810 and 830 in one composite layer structure. In this manner, it reveals an aspect of constructing an embedded magnetic component as part of the layers of the power converter.

The constituent parts 801 through 810 form a composite structure termed Integrated Magnetic Module 811. This embodiment has other constituent parts 828, 829, and 830. Inclusive with components 801 through 810, it may be viewed as forming an Integrated Magnetic Module type 811 structure. However, it may also be viewed in combination with other components shown which, in other embodiments, had formed the Integrated Power Conversion Module structure. Thus, one of the novel features of this embodiment of the disclosure is to view this embodiment as a combination of the two, namely Integrated Magnetic Module and Integrated Power Conversion Module.

Continuing with the description of the component parts with regard to FIG. 8, the present disclosure includes at least one substrate layer 812; at least one 812 substrate top and bottom layer Input-Side for installed power semiconductor components 817, at least one 812 substrate top and bottom layer Output-Side for installed power semiconductor components 818, at least one 812 substrate Input-Side area or region comprised of top, bottom and inner layers of the substrate interleaved for high frequency, high current flow and return on adjacent layers in opposing directions 819, at least one 812 substrate Output-Side area or region comprised of top, bottom and inner layers of the substrate interleaved for high frequency, high current flow and return on adjacent layers in opposing directions 820, and typically, at least one 812 substrate intermediate area or region comprised of top, bottom and inner layers of the substrate interleaved for high frequency, high current flow and return on adjacent layers in opposing directions 821, at least one 812 substrate input terminal 822, and at least one 812 substrate output terminal 823.

This FIG. 8 embodiment may have another aspect that differs from the first exemplary embodiment in that the Integrated Power Converter Module substrate area or region comprised of associated components necessary for general power conversion management, function, and control is not incorporated as part of this embodiment. In this embodiment, such functions are offloaded to an external separate assembly. The interface and signals from this separate assembly connect to the Integrated Power Conversion Module with a suitable connector 824. The component parts 812 through 824 form a different and novel type of embodiment of the Integrated Power Converter Module 825.

The Integrated Magnetic Module composite structure 811 and the Integrated Power Conversion Module composite structure 825, together form a completed Power Conversion Module, which is designed for high frequency, high power DC-DC conversion.

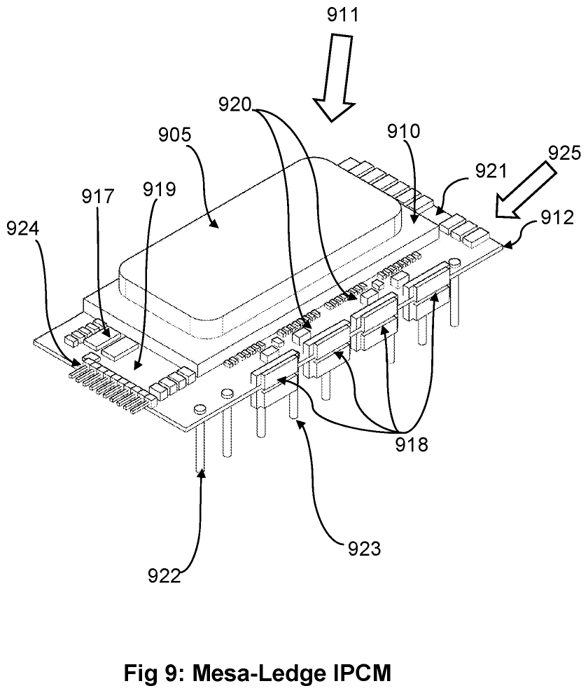

Another exemplary embodiment of the invention shown in FIG. 9 solves the problem of how to connect discrete magnetic substrates to power semiconductor components at the periphery of the magnetic substrate and optimally maximize high frequency current distribution. It is easier in embedded structures where the component can be placed directly above the windings of the magnetic substrate which is also part of the embedded structure. However, for a discrete device, the windings must terminate somewhere. This aspect of the invention solves the problem by creating separate carrier substrates for power components mounted vertically at the interface of the magnetic winding substrate terminations or interface connection. Said carrier substrates contain within interleaving layers and parallel paths for current flow at that interface or connection point. The configuration of the carrier substrate layers links together conductive current regions or traces on one layer with conductive regions or traces on other layers either adjacent or disposed a further distance away in the carrier substrate layer construction. As with FIG. 8 embodiment, the Integrated Power Conversion Module power-processing substrate is inserted into the layer stack of the Integrated Magnetic Module device. Referring to FIG. 9, the combined Integrated Magnetic Module and Integrated Power Conversion Module are shown fully assembled together into a power conversion device. The separate magnetic pole pieces and bottom plate are obscured in this view of the assembly. The top plate 905 is shown. The magnetic substrate layer 910 is shown. The optional additional substrate layer 830 from the previous FIG. 8 is now obscured. Both substrates contain the windings as in previous embodiments.

The Integrated Power Conversion Module substrate 912 is shown containing the incorporated power components mounted on it. It is inserted into the layer stack along with substrate 910 and any additional magnetic device substrates. The apertures in the magnetic device substrate layers including 910, into which magnetic pole pieces are inserted, are obscured. The same applies to apertures in Integrated Power Conversion Module substrate layer 912. This embodiment utilizes a similar magnetic structure with a baseplate [obscured] and top plate 905 which provides a cover and return path for the magnetic flux of the composite magnetic structure so formed. This embodiment follows previous embodiments but the novel combination of the components and merging of the structures 911 and 925 make this derivation unique.

Continuing with regard to FIG. 9, the Integrated Power Conversion Module substrate 912 has at least one substrate top and bottom layer Input-Side area or region for installed power semiconductor components 917. This embodiment places the installed power semiconductor components 918 in a vertically mounted configuration and locates them at the edge of substrate 912. In this FIG. 9 embodiment, the structure of the substrate 912 is modified to accommodate the power semiconductor components 918. However, it is also contemplated by this embodiment that the magnetic substrate 910 instead could have its structure modified to locate the carrier substrates at its edge.

Features in this embodiment may remain the same as in other embodiments and do not affect constructing the power components 918 in this fashion. This is shown in FIG. 9 wherein at least one Integrated Power Conversion substrate Input-Side area or region is comprised of top, bottom and inner layers of the substrate interleaved for high frequency, high current flow and return on adjacent layers in opposing directions 919, at least one substrate Output-Side area or region comprised of top, bottom and inner layers of the substrate interleaved for high frequency, high current flow and return on adjacent layers in opposing directions 920, and typically, at least one substrate intermediate area or region comprised of top, bottom and inner layers of the substrate interleaved for high frequency, high current flow and return on adjacent layers in opposing directions 921. There is at least one 912 substrate input terminal 922 and at least one 912 substrate output terminal 923.

As with the FIG. 8 embodiment, this embodiment differs from the first exemplary embodiment in that the IPCM substrate area or region comprised of associated components necessary for general power conversion management, auxiliary function, and control is not incorporated as part of this embodiment. In this embodiment, such functions are offloaded to an external separate assembly. The interface and signals from this separate assembly connect to the 912 substrate with a suitable connector 924. The component parts 912 through 924 form a different type or embodiment of the Integrated Power Converter Module 925. The Integrated Magnetic Module composite structure 911 and the Integrated Power Conversion Module composite structure 925, together form a completed Power Conversion Module, which, in this embodiment, is designed for high frequency, high power DC-DC conversion.

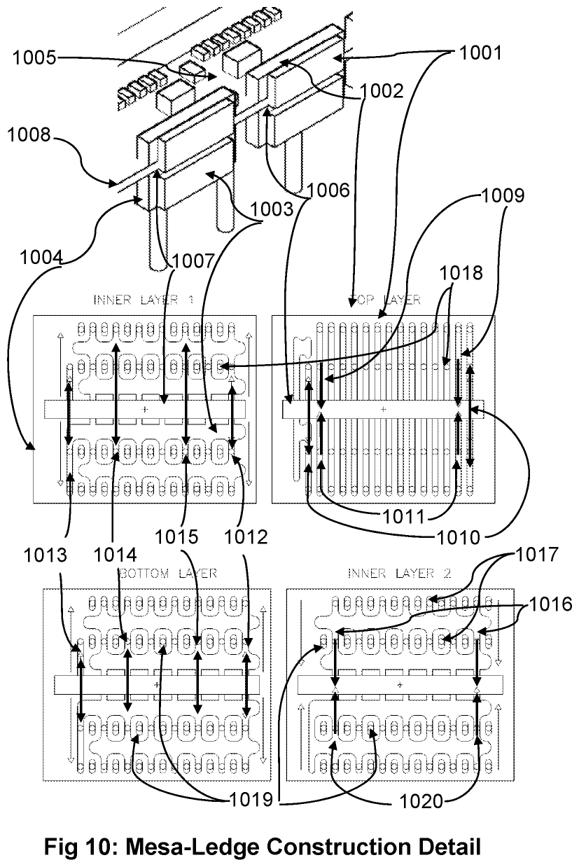

The FIG. 10 drawing illustrates one possible embodiment of the carrier substrates indicated in FIG. 9 embodiment. It shows power semiconductor components 1001 and 1003 on a vertically mounted substrate carrier 1002 and 1004 located at the edge of substrate 1008. As in FIG. 9 embodiment, the Integrated Power Conversion Module substrate 1008 is modified to accommodate the power semiconductor components. The carrier substrates 1002 and 1004 which contains layers of conductive elements or traces that allow for current flow in opposing directions in one or more combination of layers. This reduces loop inductance in the circuit to which these components connect. The implementation in the embodiment is also such as to create current flow on opposing conductive surfaces so as to maximize the high frequency current density for the conductive elements or traces in the substrate. The reduced loop inductance and alternating current resistance improves the overall performance of the circuit. To achieve this, the embodiment implements an area or region comprised of top, bottom and inner layers of the substrate, which is interleaved for high frequency, high current flow and return on adjacent layers in opposing directions.

It is important to locate the carrier substrates, winding terminations, and power components in close proximity to the interface region 1005 which itself, consists of layers of conductive traces in the Integrated Power Conversion Module substrate 1008 conducting current in one direction in one or more layers and current in opposing or opposite directions on one or more other adjacent layers. There are windows or apertures 1006 and 1007 in the substrate carriers 1002 and 1004 which mount directly on the substrate 1008 at locations in close proximity to region 1005. This is one method as shown in FIG. 10 for making this interconnect albeit other arrangements are also possible and within the context of this invention.

The substrate carriers 1002 and 1004 are comprised of one or more layers. In this embodiment. In FIG. 10, four [4] layers are shown in order to demonstrate one method. The 1st layer is designated as the top layer and it is that layer upon which the components are mounted, albeit the pattern can be repeated on the opposite or bottom side of the carrier as well. In this embodiment, the component layer implements traces in multiple locations that correspond to the multiple locations of the terminals on the semiconductor device mounted thereon. In this embodiment there is a one-to-one correspondence of traces with terminals. Other types of semiconductor components with less terminal positions would nonetheless be implemented in similar fashion. One such trace in the top half of substrate 1002 is indicated by trace 1009. The bottom half of substrate 1002 has a corresponding or “mirror trace” indicated in position 1011. The two traces shown have the current flow direction indicated by the arrow. Another pair of traces is indicated by 1010 for substrate 1002. One principle this embodiment that the carrier substrates demonstrate is that current flow is either “into” or “out of” the aperture on any given layer. It is this method that demonstrates the principle that for any particular trace chosen, the immediately adjacent trace has current flow in the opposite direction. This is repeated in such alternating sequence for the amount of terminals present on the semiconductor component for this 1st layer. In this embodiment, the technique is employed only for the layer upon which the component is mounted. Other layers adopt a different pattern or technique for subsequent layers. Other methods and patterns can be adopted that differ in amount, degree and method and accomplish the same objective.

In its goal to create multiple paths for current flow, this embodiment also creates an array of conductive paths through the layers, e.g. plated thru-holes. In substrate 1002 this is shown in positions 1017, 1018 and 1019. If superposed over one another in order, it would be readily apparent how the positions indicated proceed through to Inner Layer 1, Inner Layer 2 and the Bottom Layer. The goal is to access additional paths for current flow which is in the same direction. This creates an array of current conducting elements that enhance the effect desired. In the interest of brevity and simplicity, only the three [3] locations 1017, 1018 and 1019 are shown. However, FIG. 10 clearly shows where many of those paths or plated thru-holes repeat and are located in order to create multiple instances of the current flowing in the manner desired. This shows one technique or pattern. Other methods and patterns can be adopted that differ in amount, degree and method and accomplish the same objective.

In this embodiment, Inner Layer 1 is immediately adjacent to Top Layer. Current conducting traces 1014 and 1015 are shown with the arrows indicating direction of current flow opposite to traces 1011 in Top Layer in the layer above. In two locations of Inner Layer 1, the current conducting traces 1012 and 1013 are shown with the arrows indicating same direction of current flow 1010 in Top Layer in the layer above. The Top Layer current flow direction has alternating current flow directions due to the different function of the component terminals located on those conducting traces. In consonance with the carrier substrate aperture rule, current flow is both “into” and “out of” the aperture in order to implement the countervailing current flow. Inner Layer 1 continues the array of conductive paths through the layers, e.g. typically plated thru-holes, shown in positions 1017, 1018 and 1019. Superposed over one another in order, the positions indicated in Top Layer proceed through to Inner Layer 1. Current flow on Inner Layer 1 is in opposite directions to that on Top Layer. In two positions 1012 and 1013, there are isolating islands created for the plated thru holes so that connection may be made with layers above and below in which current flow is in the same direction.

In this embodiment, Inner Layer 2 is immediately adjacent to Inner Layer 1. Current conducting traces 1016 and 1020 are shown with the arrows indicating direction of current flow opposite to traces 1014 and 1015 of Inner Layer 1 in the layer above. In consonance with the carrier substrate aperture rule, current flow is both “into” and “out of” the aperture in order to implement the countervailing current flow with layers above and below. Inner Layer 2 continues the array of conductive paths through the layers, e.g. typically plated thru-holes shown in positions 1017, 1018 and 1019. Superposed over one another in order, the positions indicated in Top Layer and Inner Layer 1 proceed through to Inner Layer 2. Current flow on Inner Layer 2 is in opposite direction to that on Inner Layer 1. Isolating islands are created for the plated thru-holes on Inner Layer 2 so that connection may be made with layers above and below in which current flow is in the same direction. In this manner, countervailing current flow on adjacent layers is achieved.

In this embodiment, Bottom Layer is immediately adjacent to Inner Layer 2. Current conducting traces 1014 and 1015 are shown with the arrows indicating direction of current flow opposite to traces 1016 and 1020 of Inner Layer 2 in the adjacent layer above. In two locations of Bottom Layer, the current conducting traces 1012 and 1013 are shown with the arrows indicating same direction of current flow for traces 1012 and 1013 in Inner Layer 1 above as well as 1010 in Top Layer in the layer above. The Bottom Layer is a replica of Inner Layer 1. That is clearly shown by traces 1012, 1013, 1014 and 1015. In consonance with the carrier substrate aperture rule, current flow is both “into” and “out of” the aperture in order to implement countervailing current flow. Bottom Layer continues the array of conductive paths through the layers, e.g. typically plated thru-holes, shown in positions 1017, 1018 and 1019. Superposed over one another in order, the positions indicated in Top Layer proceed through to all layers above. Current flow on Bottom Layer is in opposite direction to that on Inner Layer 2. As with Inner Layer 1, there are isolating islands created for the plated thru-holes so that connection may be made with layers above in which current flow is in the same direction.

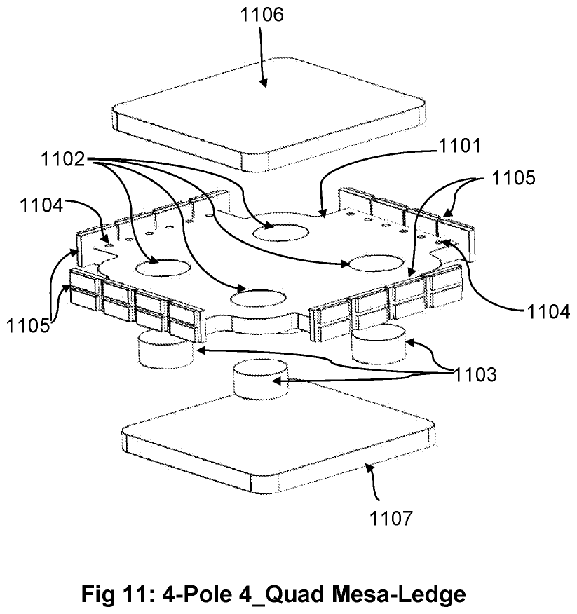

Another exemplary embodiment of the invention disclosed in FIG. 11 creates a greater number of magnetic pole pieces which thereby create a greater number of quadrants in which to mount the power semiconductor components in either horizontal or vertical fashion on the periphery of the substrate at the interconnection of the magnetic module substrate and the power-processing substrate. However, expanding the number of poles is most effective when the multiple pole pieces are configured as separable pole pieces. This takes advantage of the scalability and universality such approach affords without constraints of manufacture via mold making.

As in the FIG. 5 4-pole drawing, FIG. 11 includes [4] separate magnetic pole pieces 1103 [one cylinder is obscured in exploded view]. As in FIG. 5, there is at least one substrate layer 1101 which contains the windings.

FIG. 11 drawing includes [4] apertures 1102 in substrate layer 1101 into which magnetic pole pieces 1103 are inserted. As in FIG. 5 drawing, the FIG. 11 embodiment includes a magnetic baseplate 1107 which secures in position magnetic pole pieces 1103, and a magnetic top plate 1106 which forms a cover and return path for the magnetic flux of the composite magnetic structure. The component parts 1103 are shown in FIG. 11 as separable elements. That is, they are not physically the same homogenous structure as baseplate 1107. The embodiment shown in FIG. 11 incorporates by reference all the claims made as in embodiment shown in FIG. 5.

The FIG. 11 embodiment demonstrates a novel expansion of the embodiment of FIG. 9 wherein some or all of the power semiconductor components can be mounted vertically in a location on the perimeter or ledge on one or more sides of the power processing substrate. In this embodiment, substrate 1101 can be configured to accommodate the vertical power semiconductor components 1105 in at least one [1] quadrant and up to as many as all [4] four quadrants of the substrate 1101. For purposes of clearly explaining this embodiment, only the vertical power semiconductor components 1105 are shown. That is, the power-processing substrate 1101 is shown without the other incorporated power components mounted on it. As in previous embodiments, it can be inserted into the layer stack along with associated magnetic device substrates which contain the windings. Substrate 1101 can also contain one or more of the windings. In combination, and along with the magnetic structure, it forms a composite device or structure similar to previous embodiments and repeated herein. The novel aspect of this disclosure is to place the installed power semiconductor components 1105 in a vertically mounted configuration and to locate them at the edge of substrate 1101 in any number of quadrants or locations. To utilize this concept effectively, it is preferable to modify the structure of the substrate 1101 to accommodate the power semiconductor components 1105. The Integrated Power Conversion Module composite structure shown in FIG. 11 and the Integrated Magnetic Module composite structure, together form a completed Power Conversion Module, which, in this embodiment is designed for high frequency, high power DC-DC conversion.

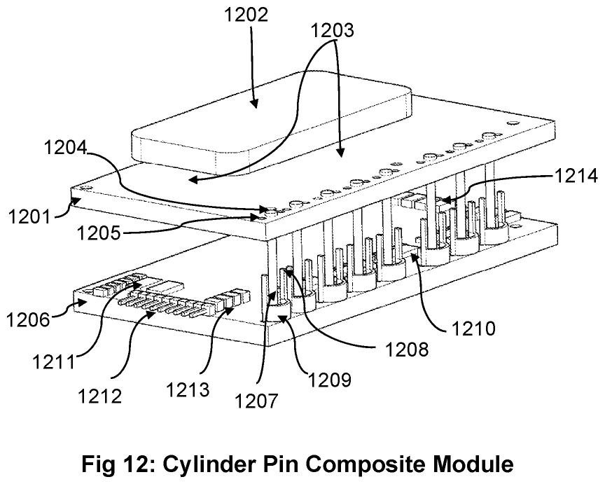

Another exemplary embodiment of the invention shown in FIG. 12 solves the problem of how to connect discrete magnetic substrates to power semiconductor components at the periphery of the magnetic substrate and optimally maximize high frequency current distribution. This disclosure does so by co-locating the terminal positions for both the magnetic composite substrate and the power-processing component substrate which thereby occupy the same position or location on both substrates. In one possible embodiment, a concentric cylinder pin terminal structure makes this possible. The cylindrical structure of the terminal creates a means of countervailing or opposing current flow at the terminal interface and within the terminal itself which maximizes ac current density, particularly at high frequencies.

Referring to FIG. 12, as with previous embodiments, this embodiment includes at least two separate magnetic pole pieces. They are not shown in this figure in order to focus on clarity of describing this embodiment. The same applies to the apertures in substrate 1201 into which the magnetic pole pieces are inserted. As in the first exemplary embodiment, there is at least one substrate layer 1201 which contains the windings 1203. As in the first exemplary embodiment, there is a magnetic base plate [obscured] and a top plate 1202 which forms a cover and return path for the magnetic flux of the composite magnetic structure.

The unique feature of this embodiment is that the terminal positions for both the magnetic device substrate and the power-processing substrate occupy the same proximate position or location on both substrates 1201 and 1206. The terminal structure that makes this possible is termed “Concentric Cylinder Pin”. When trying to electrically connect together one substrate with layers that contains the windings and one substrate with layers that contain conductive, e.g. pcb traces and components, previous embodiments have accomplished that with with physically discrete pins or with vias embedded in both substrates. The embodiment of FIG. 8 does it with the power-processing substrate inserted into the layer stack of the magnetic device substrates. This FIG. 12 embodiment does it with the concentric cylinder pin terminal structure. The advantage of doing it in this manner is the connections do not require additional space, region or location to accomplish this connection. It makes the Integrated Magnetic Module to Integrated Power Conversion Module connection in the same location as the input/output pins or terminals of the Integrated Power Conversion Module. The incorporated power components on the power-processing substrate do not need to be moved to account for the space occupied by the substrate-to-substrate connection. In fact, these components can be placed to take advantage of this method. The physical placement of these pins can be just outside the outline of the magnetic plate 1202 or on the periphery of the substrate 1206. This would make for a smaller width dimension for the finished power conversion module. Shown here in FIG. 12, the pins occupy the same positions they do in the first exemplary embodiment of FIG. 2 which are the locations of the input and output pins of the completed power conversion module. They would thus be the same width as the Integrated Power Conversion module substrate.

The cylinder pins have a concentric ring with [2] prongs 1208 which connect to the winding traces of substrate 1201 at locations 1205. On substrate 1206, this continues the intended electrical connection to the incorporated power components 1210 and 1211 on substrate 1206 via the [2] prongs 1208. There is a central pin 1207. This makes electrical connection to the input/output of the Integrated Power Conversion Module substrate 1206. It also functions to make electrical connection 1204 to the windings of substrate 1201. In many power topologies these can share a common electrical function connection to output or return [ground].

Another aspect of the disclosure is the cylindrical structure 1209. Physically, this has a function to stand off the physical space between substrate 1201 and 1206. It creates a required clearance between substrates and components 1210, 1211, 1212, 1213, and 1214. Electrically, it has a function to create a means of countervailing or opposing current flow in close proximity to the central pin or structure 1207. This maximizes ac current density at the pin location and thus maximizes ac current flow between substrates 1201 and 1206.

The Integrated Magnetic Module and Integrated Power Conversion Module structures along with the concentric cylinder pin of FIG. 12 utilized in this manner together form a completed Power Conversion Module which is designed for high frequency, high power DC-DC conversion.

1. In one first exemplary embodiment, a single or multi-pole discrete magnetic device assembly or structure with a substrate containing windings and conductive traces which is inserted and integrated into a separate main power-processing structure and assembly with a substrate which contains the power semiconductor components and other components necessary for the processing of electrical power, and at said interface and insertion points, the substrate layers of each are comprised of top, bottom and inner layers interleaved for high frequency, high current flow and return on adjacent layers and alternating layers and positions in countervailing directions, wherein:
the discrete magnetic device assembly or structure includes at least one magnetic pole piece or post, in one aspect, ferromagnetic, at least one substrate layer which contains the windings or conductive trace elements of the magnetic device, apertures in the substrate layer into which are inserted the magnetic pole pieces, a magnetic baseplate which secures in position the magnetic pole pieces and a magnetic top plate which forms a cover and return path for the magnetic flux;
the discrete magnetic device assembly or structure is 1-pole, 2-pole or multiple n-poles which encompasses the number of magnetic pole pieces or posts and apertures into which the pole pieces are inserted;
the discrete magnetic device substrate contains at least one output terminal, at least one input terminal, and may include at least one intermediate terminal;
the separate main power-processing assembly substrate has at least one cut-out into which the discrete magnetic device assembly is to be inserted, at least one terminal position, plated thru-hole or conductive via or pad, into which will be inserted at least one of the discrete magnetic device assembly input terminals, at least one terminal position into which will be inserted at least one of the discrete magnetic device assembly output terminals, and may include at least one intermediate terminal position into which will be inserted at least one of the discrete magnetic device assembly intermediate terminals;
there is at least one separate main power-processing assembly substrate Input-Side area or region and point of interface and electrical connection consisting typically of winding terminations, power semiconductors and power components into which is inserted the magnetic device structure, said region and interface which is comprised of top, bottom and inner layers of the substrate interleaved for high frequency, high current flow and return on adjacent layers and alternating layers and positions in countervailing directions;
there is at least one separate main power-processing assembly substrate Output-Side area or region and point of interface and electrical connection consisting typically of winding terminations, power semiconductors and power components into which is inserted the magnetic device structure, said region and interface which is comprised of top, bottom and inner layers of the substrate interleaved for high frequency, high current flow and return on adjacent layers and alternating layers and positions in countervailing directions;
there may be at least one Intermediate area or region and point of interface and electrical connection consisting in one aspect, of winding terminations, power semiconductors and power components into which is inserted the magnetic device structure, said region and interface which is comprised of top, bottom and inner layers of the substrate interleaved for high frequency, high current flow and return on adjacent layers and alternating layers and positions in countervailing directions.

2. A single or multi-pole discrete magnetic device assembly per claim 1 above in accordance with an alternative embodiment, that stands alone as a separate assembly unto itself, wherein:
the discrete magnetic device assembly substrate number of layers, interleave, traces, construction and patterns are independent of those of the separate main power-processing assembly substrate;
the discrete magnetic device assembly or structure magnetic pole pieces and plates may be scaled, sized and located independently and are not constrained by the external main power-processing assembly substrate or overall assembly and construction into which it is meant to be inserted;
the discrete magnetic device assembly or structure magnetic pole pieces can be single, double, or multiple pole in order to maximize power and optimize other characteristics for any power topology;
the discrete magnetic device assembly or structure magnetic pole pieces are separable pieces and as such, the tooling and manufacture is not constrained by the magnetic plate components, which are themselves separable pieces;
the apertures of the discrete magnetic device assembly or structure substrate adjust according to the size and location of the magnetic pole pieces and thus the discrete magnetic device assembly or structure substrate can be incrementally adjusted and sized in order to correspond to the exact power requirements necessary for any application or for any power topology;
the discrete magnetic device assembly or structure magnetic plates are separable pieces and as such, the tooling and manufacture is not constrained by the magnetic pole pieces, which are themselves separable pieces;
the discrete magnetic device assembly substrate may also possess features described as “fingers” or “spokes” which hold the magnetic pole pieces in position and help to center them in locations desired on the magnetic baseplate;
any separate main power-processing assembly and substrate including components, number and placement and overall design can be configured independently of the discrete magnetic device structure and may yet be designed to incorporate the discrete magnetic device structure substrate.

3. A single or multi-pole discrete magnetic device assembly or structure per claim 1 and 2 above in accordance with one aspect of the disclosure that within its layer structure incorporates interlayer vias or other conductive connections within the substrate that connect any one layer or region thereof to different layers within the substrate, said technique of connecting to adjacent and non-adjacent layers in a multi-layer substrate, wherein:
vias on one layer connect to isolated regions of copper or conductive regions, typically in the form of pcb traces, on layers directly adjacent above or below or on other non-adjacent layers disposed at a distance within the substrate, effectively allowing said one layer to occupy a portion of another layer and thus make for the current flow on one layer to also flow on another layer and to effectively share the current;
said technique of connecting to adjacent and non-adjacent layers in a multi-layer substrate creates the maximum number of regions and layers wherein current flowing in these and all layers across from insulated interfaces occurs in instances where there are countervailing directions of current flow in adjacent layers or regions;
said technique of connecting to adjacent and non-adjacent layers in a multi-layer substrate is configured and utilized for the purpose of minimizing and balancing the magneto-motive force amongst one or more layers of said substrate;
said technique of connecting to adjacent and non-adjacent layers in a multi-layer substrate is constructed in a configuration such that the isolated regions are located sufficient distance from the magnetic pole pieces and plate structures preserving the dielectric standoff voltage and creepage distance to same;
said technique of connecting to adjacent and non-adjacent layers in a multi-layer substrate is constructed to ensure that the isolated regions at such locations occupy the minimum area required at that layer to form the isolated conductive trace or region and that it does not subtract significantly from the overall conductive area, thus preserving a maximum current density for any particular layer or conductive trace on that layer;
said technique of connecting to adjacent and non-adjacent layers in a multi-layer substrate which creates an effect at such locations that the current flow occurs in a region of highest magnetic flux concentration.

4. A discrete magnetic device assembly or structure per claim 1 and 2 above in accordance with one aspect of the disclosure wherein a separate hybrid substrate is inserted into the substrate layer stack of the discrete magnetic structure wherein:
the separate hybrid substrate is comprised of one or a number of layers and is inserted into the magnetic layer stack structure of the core window formed by the magnetic structure with its substrates, which contain conductive winding layers, and does so by apportioning said magnetic layer structure within the stack and allocating space therein;
the separate hybrid substrate may contain power components mounted thereon;
the separate hybrid substrate may also contain windings themselves utilized as part of the magnetic element layer stack structure;
the separate and external main power processing substrate may also continue to contain power semiconductor and other components mounted thereon;
the separate hybrid substrate may connect to the magnetic substrate structure with vias, pads, castellations, or terminals specially designed for this connection;
the separate hybrid substrate may be embedded along with the magnetic structure substrates into one composite embedded layer structure, in accordance with another aspect of this disclosure;
at the point of electrical connection and interface the separate hybrid substrate, may contain areas or regions comprised of top, bottom and inner layers of the substrate interleaved for high frequency, high current flow and return on adjacent layers in opposing or countervailing directions;
the separate hybrid substrate can be inserted anywhere in the layer stack of the magnetic substrate structure and the layers therein adjusted as needed to enable more flexibility in the configuration and placement of the power and other components mounted on the hybrid substrate.

5. A discrete magnetic device assembly or structure per claim 1, 2, 3 and 4 above in accordance with one aspect of the disclosure, wherein a separate substrate inserted into the substrate layer stack of the discrete magnetic structure creates one or more separate carrier substrates for power components mounted vertically at the interface of the magnetic winding substrate terminations and same interface connection with said power components, wherein:
said carrier substrate embodiment implements an area or region comprised of top, bottom and inner layers of the substrate, which is interleaved for high frequency, high current flow and return on adjacent layers in opposing directions and also creates parallel paths for current flow at that interface or connection point;
the configuration of the carrier substrate layers links together conductive current regions or traces on one layer with conductive regions or traces on other layers of the carrier substrates either adjacent to or disposed a further distance away in the layers of the carrier substrate, creating multiple paths for current flow, utilizing an array of conductive paths through the layers, plated thru-holes or vias in one aspect of the embodiment;
in accordance with one embodiment, the carrier substrates are in a location on the perimeter or ledge on one or more sides of the separate substrate;
in accordance with one embodiment, the power semiconductor components are mounted on a carrier substrate with an aperture in the carrier substrate that fits directly into an array of conductive slots, fingers, or promontories in the separate magnetic structure substrate in closest proximity or intersection to the region wherein the windings of the separate magnetic structure substrate and input, output, and intermediate connections are located;
a carrier substrate layer contains traces that have a corresponding or mirror trace in positions on opposite sides of the aperture;
a carrier substrate trace methodology implements current flow that is either into or out of the aperture;
there is at least one layer of the carrier substrate upon which the components are mounted, but the pattern can be repeated on the opposite or bottom side of the carrier substrate as well;
the component layer of the carrier substrate implements traces in multiple locations that correspond to the multiple locations of the terminals on the power semiconductor device mounted thereon which may or may not possess a one-to-one correspondence of traces with device terminals;
a carrier substrate trace methodology and configuration is such that for any particular trace chosen, the immediately adjacent trace has current flow in the opposite direction;
a carrier substrate trace methodology repeats in alternating sequence for the number of terminals or conductive pads present on the power semiconductor component;
a carrier substrate trace methodology creates multiple paths for current flow in the same direction on different layers, utilizing isolating conductive area or regions on designated layers and connecting same through an array of conductive paths through the layers, in one aspect, plated thru-holes or vias;
the carrier substrate vertical construction of power semiconductor components facilitates mounting of a thermal interface or heat sink separable from or independent to that of the complete structure of the power conversion module;
the carrier substrate vertical construction of power semiconductor components mounted on a carrier substrate enables that portion of the overall construction to be changed or adapted without affecting other parts of the construction of the separate main power-processing assembly and substrate itself or the entirety of the power conversion module;
the carrier substrates of the discrete magnetic device structure substrate adjust according to the size and location of the magnetic device structure substrate allowing the discrete magnetic device assembly or structure substrate to be incrementally adjusted and sized in order to correspond to the exact power requirements necessary for any application or for any power topology, thus forming a complete power conversion module.

6. An embodiment similar to claim 5 above, in which the separate external main power-processing assembly substrate is configured and constructed to have one or more separate carrier substrates for power components mounted vertically at the interface of the magnetic structure substrate winding terminations and interface connection with said power components, wherein:
in such aspect or embodiment, the carrier substrate is inserted into the separate power assembly substrate directly at the point of interface and connection with the carrier substrates and the magnetic element substrate and the separate external main power-processing substrate implements an area or region comprised of top, bottom and inner layers of the substrate, which is interleaved for high frequency, high current flow and return on adjacent layers in opposing directions and also creates parallel paths for current flow at that interface or connection point;
all of the aspects and embodiments of claim 5 apply to and are incorporated herein to claim 6.

7. A method for locating the power components of the separate power processing assembly substrate on the periphery of the substrate which corresponds to the same location and interface point of the discrete magnetic substrate winding terminations by co-locating the terminals which make this connection on both substrates wherein:
in one aspect of this embodiment, a concentric cylinder pin terminal structure makes this connection and said cylindrical structure of the terminal creates a means of countervailing or opposing current flow within the terminal itself and at the terminal interface which maximizes current flow and distribution, particularly at high frequencies;
in one aspect of this embodiment, a terminal structure is configured with a cylindrical pin which is utilized for connecting electrically together one substrate with layers that contains conductive winding traces to one substrate with layers that contain conductive traces and power components at the same position or terminal location on the substrate;
the terminal positions for both the magnetic device substrate and the power assembly substrate occupy the same proximate position or location on both substrates;
the cylinder pins that make the substrate-to-substrate connection contain a concentric ring with at least one and preferably two prongs which connect to the winding traces of one substrate and connect as well to the incorporated power components on the power assembly substrate via these prongs;
the cylinder pins that make the substrate-to-substrate connection contain a central pin making electrical connection at input/output locations of the power assembly substrate and also make electrical connection to the windings of the magnetic device substrate;
the cylinder pins that make the substrate-to-substrate connection contain a cylindrical structure which physically, has the function to stand off the physical space between substrates by creating a certain clearance between substrates and components and also, electrically, has the function to create a means of countervailing or opposing current flow in close proximity to the central pin in order to maximize ac current flow between substrates at high frequencies.

8. A multi-pole discrete magnetic device assembly in accordance with an alternative embodiment pursuant to claims 1, 2, 3, 4, 5, 6, and 7 in which the separate power-processing substrate that is inserted into the magnetic layer structure and its substrates, and upon which some or all of the power semiconductor components may be placed, utilizes vertically mounted carrier substrates in at least one [1] quadrant and up to as many as [4] four or more quadrants in a location on the perimeter or ledge of the separate power-processing substrate, wherein:
all of the aspects and embodiments of claim 2 apply to and are incorporated herein to claim 8.

9. A separate main power-processing assembly and substrate in an alternative embodiment in which the substrate area is allocated only to those components necessary for core power conversion function and associated components related to management function and control are offloaded to an external assembly or structure to which the power conversion module connects, and the interface and signals from this separate assembly connect to the power-processing substrate or module with a suitable connector or daughter card.
